(19) United States
(12) Patent Application Publication
(10) Pub. No.: US 2008/0048338 A1
(43) Pub. Date: Feb. 28, 2008

(54) Semiconductor Device and Fabrication Method Thereof

(76) Inventor: HAN CHOON LEE, Songpa-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/846,003

(22) Filed: Aug. 28, 2007

(30) Foreign Application Priority Data
Aug. 28, 2006 (KR) 10-2006-0081968

(51) Int. Cl. H01L 23/48; H01L 21/4763

(52) U.S. Cl. 257/774; 438/637; 257/E21.577; 257/E21.585

(57) ABSTRACT

A semiconductor device and a fabricating method thereof are provided. An insulating layer pattern has a via hole exposing a lower metal layer, and a copper via is provided inside the via hole. A TiSiN layer is disposed on the insulating layer pattern and the copper via, and an interconnection structure is disposed on the TiSiN layer.

### CROSS-REFERENCE TO RELATED APPLICATION

The present application claims the benefit under 35 U.S.C. §119 of Korean Patent Application No. 10-2006-0081968, filed Aug. 28, 2006, the subject matter of which is hereby incorporated by reference in its entirety.

### BACKGROUND

As semiconductor devices move toward higher performance speeds and become more integrated, the transistors of the devices become smaller and smaller. Furthermore, as the transistors become more integrated, interconnections of the semiconductor device become finer. This leads to a degradation of the high-speed performance of the semiconductor device due to delay or distortion of a signal applied to the interconnection.

Accordingly, copper interconnections using copper with excellent electro-migration properties are sometimes used. These copper interconnections have lower resistance than the aluminum or aluminum alloy interconnections that are commonly used in semiconductor devices.

In forming a copper interconnection, a copper layer may be deposited and then etched. However, since copper has poor etching properties, part of the copper interconnection is often oxidized during etching.

Thus, a damascene process is sometimes used in order to overcome the etching difficulty of copper. According to the damascene process, a trench and a contact hole are formed in an insulating layer, and a copper layer is deposited on the insulating layer, filling the trench and the contact hole. Thereafter, the copper layer is planarized using a chemical mechanical polishing (CMP) process to form a copper interconnection in the trench and the contact hole.

In addition to being used to form a metal interconnection in a semiconductor device, the damascene process is also sometimes used to form a bit line or a word line for a memory device. The damascene process allows for a contact hole (or via hole) to be formed for connecting upper and lower metal interconnections to each other in a multi-layered metal interconnection structure. Furthermore, the damascene process also has the advantage of making it possible to remove a stepped portion of the metal interconnection, thereby facilitating follow-up processes.

In many semiconductor devices, a lead frame serves as a terminal through which an external signal is provided. However, when a semiconductor device utilizes a copper metal interconnection, it is difficult to electrically connect it to a lead frame. It is also difficult to wire-bond the lead frame to the copper interconnection through an aluminum wire or other metal wire.

Therefore, an aluminum pattern or an aluminum interconnection serving as a bump is often formed on a copper interconnection, allowing a semiconductor device to be electrically connected to a lead frame.

FIG. 1 is a micrograph showing copper diffusion into an aluminum interconnection in a typical semiconductor device.

Referring to FIG. 1, copper ions diffuse into an aluminum interconnection 1 from a copper interconnection, even when a diffusion barrier layer between the copper interconnection and the aluminum interconnection 1 is formed. This can cause the electrical properties of the copper interconnection to be degraded. Moreover, due to copper 2 disposed on the aluminum interconnection 1, caused by copper diffusion into the aluminum interconnection 1, a semiconductor device often fails to wire-bond to a lead frame.

Thus, there exists a need in the art for a semiconductor device and a method for forming the same which inhibits the diffusion of copper into an interconnection of another metal.

### BRIEF SUMMARY

Embodiments of the present invention provide a semiconductor device and a method of fabricating the same. An embodiment provides a metal interconnection for a semiconductor device and method of fabricating the same.

A semiconductor according to an embodiment can include: an insulating layer pattern; a copper via; a titanium silicon nitride (TiSiN) layer disposed on the insulating layer pattern and the copper via; and an interconnection structure disposed on the TiSiN layer.

In a method according to an embodiment, an insulating layer can be formed on a substrate, and a via hole can be formed in the insulating layer, exposing a lower metal layer. A copper via can be formed inside the via hole, and a TiSiN layer can be formed on the insulating layer and the copper via. An interconnection structure can then be formed on the TiSiN layer.

The details of one or more embodiments are set forth in the accompanying drawings and the detailed description below. Other features will be apparent to those skilled in the art from the detailed description, and the drawings, and from the appended claims.

### BRIEF DESCRIPTION OF THE DRAWINGS

FIG. 1 is a micrograph showing copper diffusion into an aluminum interconnection in a typical semiconductor device.

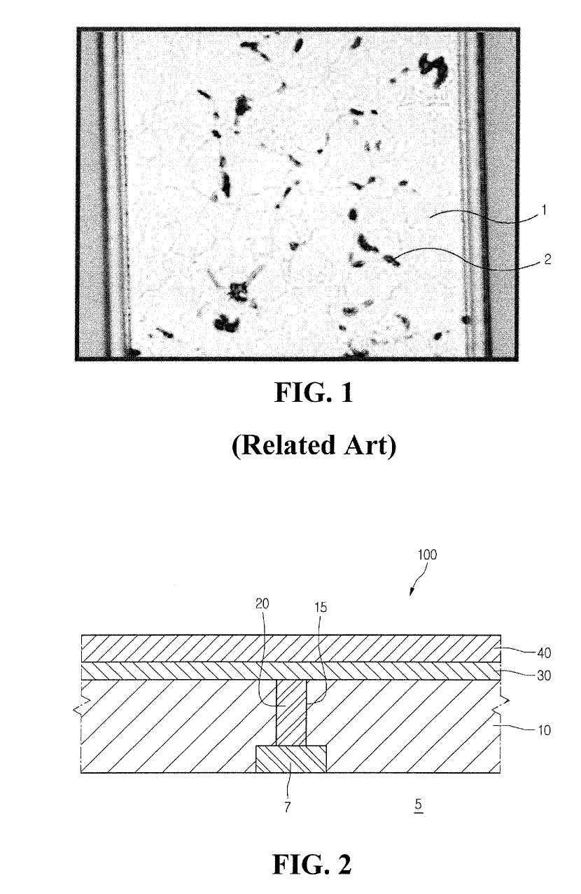

FIG. 2 is a cross-sectional view of a metal interconnection of a semiconductor device according to an embodiment of the present invention.

FIG. 3 is a cross-sectional view of a metal interconnection of a semiconductor device according to an embodiment of the present invention.

FIG. 4 is a cross-sectional view of a metal interconnection of a semiconductor device according to an embodiment of the present invention.

FIGS. 5 to 9 are cross-sectional views illustrating a method of fabricating a semiconductor device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

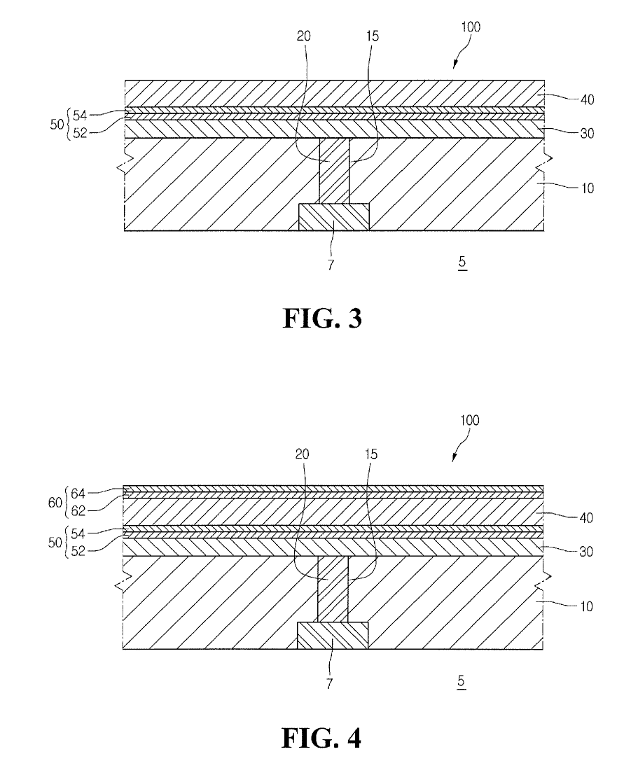

Referring to FIG. 2, in an embodiment of the present invention, a metal interconnection 100 can include an insulating layer pattern 10, a copper via 20, a titanium silicon nitride (TiSiN) layer 30, and an interconnection structure 40.

The insulating layer pattern 10 can be disposed on a substrate 5. The substrate 5 can include, for example, silicon. The insulating layer pattern 10 can include an oxide layer, a nitride layer, or both.

The insulating layer pattern 10 can have a via hole 15 exposing a lower metal layer 7 interposed between the substrate 5 and the insulating layer pattern 10.

In an embodiment, the insulating layer pattern 10 can also have a trench (not shown) having a predetermined depth. The via hole 15 and/or the trench can be used in forming a copper interconnection later. When there is no trench, a single damascene process can be performed. When a trench is present, a double damascene process can be performed.

The copper via 20 can be disposed inside the via hole 15 in the insulating layer pattern 10. The copper via 20 can include a copper seed layer (not shown) disposed inside the via hole 15 and a copper layer covering the copper seed layer.

The TiSiN layer 30 can be disposed on the insulating layer pattern 10 and the copper via. The TiSiN layer can be disposed as a thin film or a predetermined pattern. The TiSiN layer 30 can serve as a diffusion barrier layer to inhibit copper ions contained in the copper via 20 from diffusing into the interconnection structure 40. The TiSiN layer 30 can electrically connect the copper via 20 to the interconnection structure 40 because the TiSiN layer 30 is electrically conductive. The dense structure of the TiSiN layer 30 helps inhibit the copper ions contained in the copper via 20 from diffusing into the interconnection structure 40.

The interconnection structure 40 can be disposed on the TiSiN layer 30. The interconnection structure 40 can include, for example, an aluminum interconnection or an aluminum alloy layer.

The TiSiN layer inhibits copper ions contained in the copper via 20 from diffusing into the interconnection structure 40, thereby making it possible to inhibit the interconnection structure 40 from being contaminated due to copper diffusion.

In an embodiment, the metal interconnection 100 can include a first diffusion barrier layer 50.

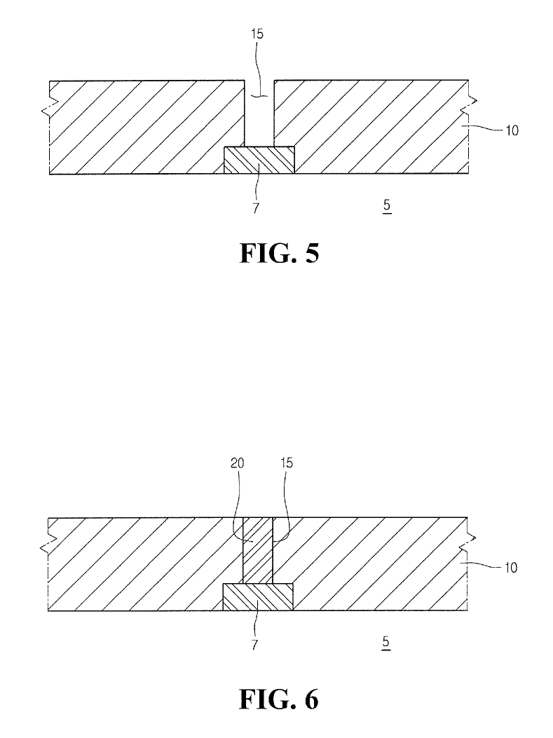

Referring to FIG. 3, the first diffusion barrier layer 50 can be disposed on the TiSiN layer 30 and under the interconnection structure 40. The first diffusion barrier layer 50 can help inhibit copper ions from diffusing into the interconnection structure 40.

The first diffusion barrier layer 50 can include a first titanium (Ti) layer 52 disposed on the TiSiN layer 30 and a first titanium nitride (TiN) layer 54 disposed on the first Ti layer 52 and in contact with the interconnection structure 40.

In an embodiment, the metal interconnection 100 can include a second diffusion barrier layer 60.

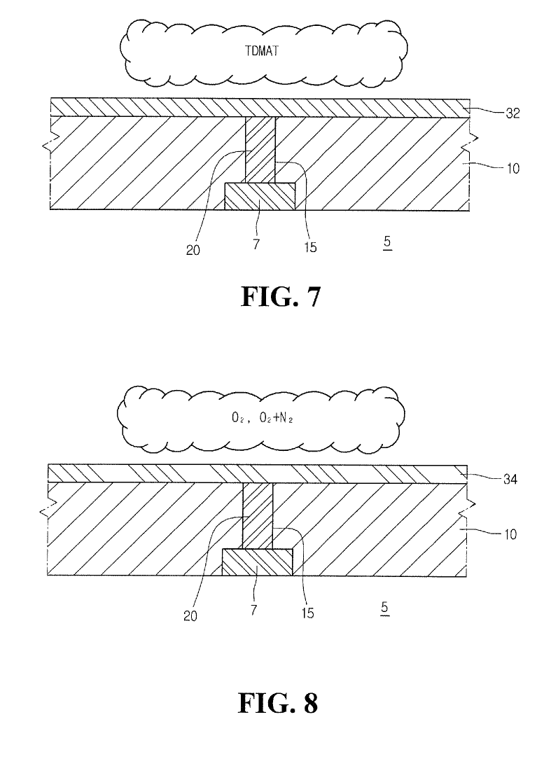

Referring to FIG. 4, the second diffusion barrier layer 60 can be disposed on the interconnection structure 40. The second diffusion barrier layer 60 can include a second Ti layer 62 disposed on the interconnection structure 40, and a second TiN layer 64 disposed on the second Ti layer 62. In an embodiment, the second diffusion barrier layer 60 can be disposed on the interconnection structure 40 while no first diffusion barrier layer 50 is present.

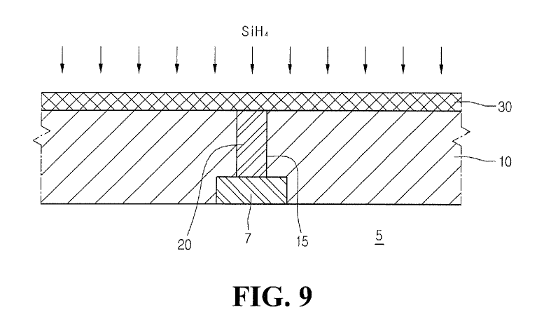

FIGS. 5 to 9 are cross-sectional views illustrating a method of fabricating a metal interconnection of a semiconductor device according to an embodiment of the present invention.

Referring to FIG. 5, a lower metal layer 7 can be formed on a substrate 5. The substrate can be a silicon substrate. An insulating layer can be formed on the substrate 5 and the lower metal layer 7. The insulating layer can include an oxide layer, a nitride layer, or both.

After forming the insulating layer, a photoresist film (not shown) can be formed on the insulating layer. The photoresist film can be patterned by a photolithography process, for example an exposure and development process, to form a photoresist pattern (not shown) on the insulating layer.

The photoresist pattern can be shaped such that it has an opening over at least part of the lower metal layer 7.

The insulating layer can be etched using the photoresist pattern as an etch mask, thereby forming an insulating layer pattern 10 having a via hole 15 that exposes the lower metal layer 7.

Referring to FIG. 6, after forming the insulating layer pattern 10 having the via hole 15, a copper via 20 can be formed in the via hole 15.

A copper seed layer (not shown) can be formed in the via hole 15. Then, copper can be formed on the copper seed layer such that the via hole 15 is filled by copper, thereby forming the copper via 20. A diffusion barrier layer can be formed in the via hole 15 before forming the copper seed layer. The copper via 20 can be formed using any reasonable method known in the art.

A TiSiN layer can be formed on the insulating layer pattern 10 to help inhibit the diffusion of copper ions contained in the copper via 20.

Hereinafter, a process that can be used to form the TiSiN layer will be described in more detail with reference to FIGS. 7 to 9.

Referring to FIG. 7, TrakisDiMethylAmidoTitanium (TDMAT, Ti[N(CH₃)₂]₄) can be deposited on the insulating layer pattern 10 and the copper via 20 to form a TiCNH layer 32, which can serve as a first medium layer. The TDMAT can be deposited using a chemical vapor deposition (CVD) process.

Referring to FIG. 8, a TiN layer 34 serving as a second medium layer can be formed on the insulating layer pattern 10 by reacting the TiCNH layer 32 through plasma treatment. The TiN layer 34 can be formed by reacting the TiCNH layer 32 with oxygen in hydrogen and ambient nitrogen through plasma treatment. In an embodiment, the TiN layer 34 can be formed by reacting the TiCNH layer 32 with oxygen and nitrogen in hydrogen and ambient nitrogen through plasma treatment. In another embodiment, the TiN layer 34 can be formed by reacting the TiCNH layer 32 with nitrogen through plasma treatment.

Referring to FIG. 9, after forming the TiN layer 34 serving as the second medium layer, a silicon compound can be provided on the TiN layer 34, thereby forming a TiSiN layer 30 on the insulating layer pattern 10. The silicon compound can be silane (SiH₄).

The TiSiN layer 30 can be obtained by forming the TiN layer 34 after forming the TiCNH layer 32 using the TDMAT, and thereafter reacting silane with the TiN layer 34. The TiSiN layer 30 can have a dense texture, helping it inhibit the diffusion of copper ions contained in the copper via 20 and also helping it electrically connect the copper via 20 to an interconnection structure 40.

Referring back to FIG. 2, the interconnection structure 40 can be formed on the TiSiN layer 30. The interconnection structure can include aluminum. Referring back to FIG. 3, in an embodiment, the first diffusion barrier layer having a TiN/Ti structure can be formed on the TiSiN layer 30. Referring to FIG. 4, in an embodiment, the second diffusion barrier layer 60 having a TiN/Ti structure can be formed on the interconnection structure 40. In an embodiment, the second diffusion barrier layer 60 having a TiN/Ti structure can be formed on the interconnection structure 40 while no first diffusion barrier layer 50 is formed.

In many embodiments of the present invention, a TiSiN layer is present between a copper via and an interconnection structure and inhibits diffusion of copper ions from the copper via to the interconnection structure. Therefore, copper ions can be effectively inhibited from diffusing into an interconnection structure containing aluminum.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
an insulating layer pattern on a substrate, and having a via hole exposing a lower metal layer;
a copper via in the via hole;
a titanium silicon nitride (TiSiN) layer on the insulating layer pattern and the copper via; and
an interconnection structure on the TiSiN layer.

2. The semiconductor device according to claim 1, wherein the interconnection structure comprises aluminum.

3. The semiconductor device according to claim 1, further comprising a first diffusion barrier layer on the TiSiN layer and under the interconnection structure.

4. The semiconductor device according to claim 3, wherein the first diffusion barrier layer comprises:
a first titanium (Ti) layer on the TiSiN layer; and
a first titanium nitride (TiN) layer on the first Ti layer and contacting the interconnection structure.

5. The semiconductor device according to claim 3, further comprising a second diffusion barrier layer on the interconnection structure.

6. The semiconductor device according to claim 5, wherein the second diffusion barrier layer comprises:
a second Ti layer on the interconnection structure; and
a second TiN layer on the second Ti layer.

7. The semiconductor device according to claim 1, further comprising a second diffusion barrier layer on the interconnection structure.

8. The semiconductor device according to claim 7, wherein the second diffusion barrier layer comprises:
a second Ti layer on the interconnection structure; and
a second TiN layer on the second Ti layer.

9. A method for fabricating a semiconductor device, comprising:
forming a via hole in an insulating layer, the via hole exposing a lower metal layer;
forming a copper via inside the via hole;
forming a TiSiN layer on the insulating layer and the copper via; and
forming an interconnection structure on the TiSiN layer.

10. The method according to claim 9, wherein the forming of the TiSiN layer comprises:
forming a TiCNH layer on the insulating layer and the copper via by depositing TDMAT (TrakisDiMethylAmidoTitanium, Ti[N(CH₃)₂]₄);
forming a TiN layer on the insulating layer and the copper via by reacting the TiCNH layer through plasma treatment; and
performing a silicon compound treatment on the TiN layer.

11. The method according to claim 10, wherein depositing the TDMAT comprises performing a chemical vapor deposition process.

12. The method according to claim 10, wherein the TiN layer is formed by reacting the TiCNH layer with oxygen in hydrogen and nitrogen ambient through plasma treatment.

13. The method according to claim 10, wherein the TiN layer is formed by reacting the TiCNH layer with oxygen and nitrogen in hydrogen and ambient nitrogen through plasma treatment.

14. The method according to claim 10, wherein the silicon compound treatment is a silane (SiH₄) treatment.

15. The method according to claim 9, wherein the interconnection structure comprises aluminum.

16. The method according to claim 9, further comprising forming a first diffusion barrier layer on the TiSiN layer.

17. The method according to claim 16, wherein forming a first diffusion barrier layer comprises:
forming a first Ti layer on the TiSiN layer; and
forming a first TiN layer on the first Ti layer.

18. The method according to claim 16, further comprising forming a second diffusion barrier layer on the interconnection structure.

19. The method according to claim 9, further comprising forming a second diffusion barrier layer on the interconnection structure.

20. The method according to claim 19, wherein forming a second diffusion barrier layer comprises:
forming a second Ti layer on the interconnection structure; and
forming a second TiN layer on the second Ti layer.
